(19) United States
(12) Patent Application Publication
(10) Pub. No.: US 2026/0299425 A1
(43) Pub. Date: Oct. 1, 2026

(54) DATA PROCESSING METHOD, CHARGED PARTICLE BEAM WRITING METHOD, CHARGED PARTICLE BEAM WRITING APPARATUS, AND COMPUTER READABLE RECORDING MEDIUM

(71) Applicant: NuFlare Technology, Inc., Yokohama-shi (JP)

(72) Inventor: Yuko KAJIWARA, Yokohama-shi (JP)

(73) Assignee: NuFlare Technology, Inc., Yokohama-shi (JP)

(21) Appl. No.: 19/457,581

(22) Filed: Jan. 23, 2026

(30) Foreign Application Priority Data
Mar. 26, 2025 (JP) 2025-051990

(51) Int. Cl. G03F 7/20

(52) U.S. Cl. CPC G03F 7/2059; G03F 7/2037

(57) ABSTRACT

In one embodiment, a data processing method includes acquiring a plurality of first control points of a first parametric curve representing a curve edge of a pattern defined in writing data, acquiring bias amounts for points on the first parametric curve corresponding to a plurality of parameter values, and determining a plurality of second control points such that norms of positional differences between points obtained by shifting the points on the first parametric curve by the bias amounts and points corresponding to the plurality of parameter values on a second parametric curve represented by the plurality of second control points, become small.

### CROSS REFERENCE TO RELATED APPLICATION

This application is based upon and claims benefit of priority from the Japanese Patent Application No. 2025-51990, filed on Mar. 26, 2025, the entire contents of which are incorporated herein by reference.

### FIELD

The present invention relates to a data processing method, a charged particle beam writing method, a charged particle beam writing apparatus, and a computer readable recording medium.

### BACKGROUND

As LSI circuits are increasing in density, the line width of circuits of semiconductor devices is becoming finer. To form a desired circuit pattern onto a semiconductor device, a method of reducing and transferring, by using a reduction-projection exposure apparatus, onto a wafer a highly precise original image pattern formed on a quartz is employed. The highly precise original image pattern is written by using an electron beam writing apparatus, in which a technology commonly known as electron beam lithography is used.

The electron beam writing apparatus performs rasterization processing to calculate a coverage (area density) of an input figure for each pixel divided into predetermined-size sections, and controls an irradiation amount of each beam based on the calculated values.

In addition, the electron beam writing apparatus performs edge enhancement processing, which increases an irradiation amount for an edge region of the pattern and reduces an irradiation amount for a region located inside the edge region, to improve the resolution and reduce edge position errors. For example, in the edge enhancement processing, bias processing, which shifts edges of a pattern 300 by a predetermined bias amount, is performed to generate a reduced pattern 302, as illustrated in FIG. 10. A region obtained by removing the reduced pattern 302 from the pattern 300 is an edge region 304.

Then, the rasterization processing is performed on the pattern 300 and the reduced pattern 302 to calculate an irradiation amount for each pixel. The irradiation amount calculated for the pattern 300 is multiplied by a coefficient larger than a coefficient used to multiply the irradiation amount calculated for the reduced pattern 302. By obtaining a difference between the irradiation amounts multiplied by the respective coefficients, the irradiation amounts can be calculated so as to increase the irradiation amount for the edge region 304 and reduce the irradiation amount for the region (reduced pattern 302) inside the edge region 304.

Alternatively, the edge region 304 is obtained by removing the reduced pattern 302 from the pattern 300 and then the rasterization processing may be performed on the reduced pattern 302 and the edge region 304. The edge enhancement processing can be also performed by multiplying the irradiation amount calculated for the edge region 304 by a coefficient larger than a coefficient used to multiply the irradiation amount calculated for the reduced pattern 302.

When the input figure includes a curve, the curve may be expressed by a parametric curve, such as a cubic Bezier curve, and writing data having positional information of control points of the parametric curve may be generated and input to a writing apparatus.

When the bias processing is performed in the writing apparatus, there is a problem that an edge obtained by simply shifting the positions of the control points included in the writing data by a bias amount deviates significantly from an ideal edge. For example, as illustrated in FIG. 11, an ideal edge obtained by shifting a curve K0 expressed by control points C0 to C3 by a predetermined bias amount is a curve K1. Meanwhile, an edge expressed by control points C10 to C13 obtained by shifting the control points C0 to C3 by a predetermined bias amount is a curve K2. The deviation between the curve K1 and the curve K2 affects writing accuracy.

### BRIEF DESCRIPTION OF THE DRAWINGS

FIG. 1 is a schematic diagram of a charged particle multi beam writing apparatus according to an embodiment of the present invention.

FIG. 2 is a plan view of a shaping aperture array substrate.

FIG. 3 is a diagram illustrating an example of a cubic Bezier curve.

FIG. 4 is a diagram illustrating an example of a cubic Bezier curve.

FIG. 5 is a flowchart illustrating a writing method according to the embodiment.

FIG. 6 is a diagram illustrating the bias amount of a curve.

FIG. 7 is a diagram illustrating a curve after bias processing.

FIG. 8 is a diagram illustrating a reduced pattern and edge region after bias processing.

FIG. 9 is a diagram illustrating control points of a Bezier curve after bias processing.

FIG. 10 is a diagram illustrating an example of bias processing.

FIG. 11 is a diagram illustrating bias processing of a curve according to a comparative example.

### DETAILED DESCRIPTION

In one embodiment, a data processing method includes acquiring a plurality of first control points of a first parametric curve representing a curve edge of a pattern defined in writing data, acquiring bias amounts for points on the first parametric curve corresponding to a plurality of parameter values, and determining a plurality of second control points such that norms of positional differences between points obtained by shifting the points on the first parametric curve by the bias amounts and points corresponding to the plurality of parameter values on a second parametric curve represented by the plurality of second control points, become small.

Embodiments of the present invention will be described below with reference to the drawings. In the embodiments, a configuration using an electron beam as an example of a charged particle beam will be described. However, the charged particle beam is not limited to an electron beam and may be, for example, an ion beam.

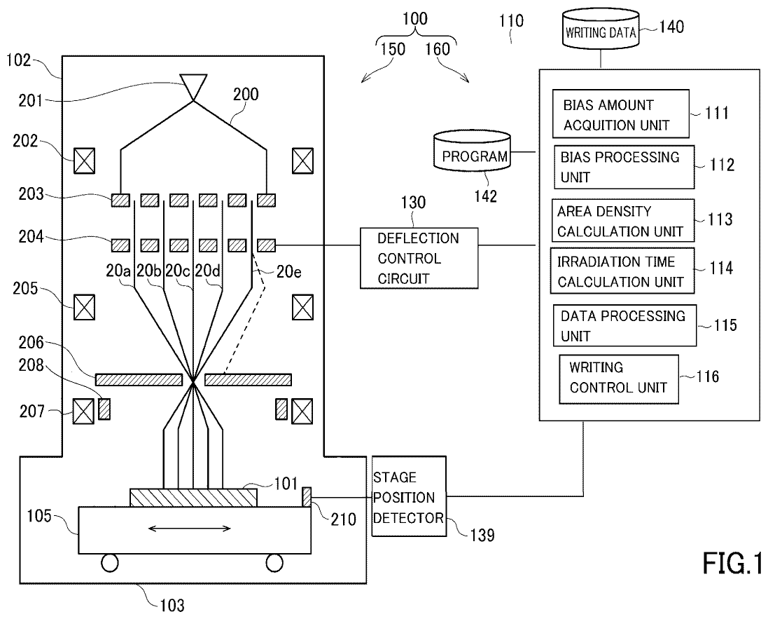

FIG. 1 is a schematic configuration diagram of a writing apparatus 100 according to an embodiment. As illustrated in FIG. 1, the writing apparatus 100 includes a writing unit 150 and a control unit 160. The writing apparatus 100 is an example of a charged particle multi beam writing apparatus. The writing unit 150 includes an electron optical column 102 and a writing chamber 103. In the electron optical column 102, an electron source 201, an illumination lens 202, a shaping aperture array substrate 203, a blanking aperture array substrate 204, a reducing lens 205, a limiting aperture member 206, an objective lens 207, and a deflector 208 are disposed.

In the writing chamber 103, an XY stage 105 is disposed. A substrate 101 on which a pattern is to be written is disposed on the XY stage 105. The substrate 101 is, for example, a mask blank or a semiconductor substrate (silicon wafer). Furthermore, a mirror 210 for position measurement is disposed on the XY stage 105.

The control unit 160 includes a control computer 110, a deflection control circuit 130, a stage position detector 139, and storage units 140 and 142. The storage unit 140 stores writing data received from an external source. In the writing data, information on a plurality of figure patterns describing semiconductor circuit patterns to be formed on the substrate 101 is defined. The figure patterns include curves, and their shapes are defined, for example, by cubic Bezier curves.

The control computer 110 includes a bias amount acquisition unit 111, a bias processing unit 112, an area density calculation unit 113, an irradiation time calculation unit 114, a data processing unit 115, and a writing control unit 116. The respective units of the control computer 110 may be implemented by hardware, such as electric circuits, or may be implemented by software, such as programs that execute these functions. Alternatively, each unit of the control computer 110 may be implemented by a combination of hardware and software. When each unit of the control computer 110 is implemented by software, a program that implements at least part of functions of the control computer 110 is stored in the storage unit 142 (recording medium), such as a CD-ROM (compact disc read only memory). The control computer 110 is a computer having a central processing unit (CPU), and the CPU reads out and executes the program. The storage unit 142 is not limited to a removable recording medium, such as a magnetic disk or optical disc, but may be a non-removable recording medium, such as a hard disk device or memory.

The stage position detector 139 irradiates the mirror 210 with a laser, receives the reflected light, and detects the position of the XY stage 105 based on the principle of laser interferometry.

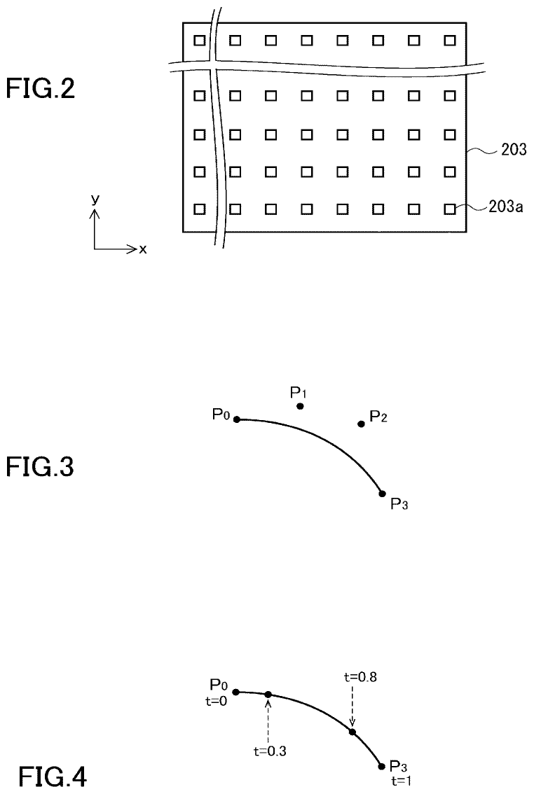

FIG. 2 is a conceptual diagram illustrating a configuration of the shaping aperture array substrate 203. As illustrated in FIG. 2, the shaping aperture array substrate 203 has a plurality of openings 203a formed at a predetermined pitch along a longitudinal direction (y direction) and a lateral direction (x direction). The openings 203a are preferably formed as rectangles or circles of the same dimensions. Part of an electron beam 200 passes through the plurality of openings 203a, and thus multi-beams 20a to 20e are formed.

The blanking aperture array substrate 204 has passage holes at positions corresponding to the openings 203a of the shaping aperture array substrate 203. A blanker comprising a pair of electrodes is disposed in each passage hole. Of the two electrodes of the blanker, for example, one electrode is grounded and kept at a ground potential, and the other electrode is switched to a ground potential or a potential other than the ground potential. This switches the deflection of a beam passing through the passage hole on or off, thereby performing blanking control. When the blanker does not deflect a beam, the beam is turned on. When the blanker deflects a beam, the beam is turned off. In this way, the plurality of blankers perform blanking deflection on the corresponding beams of the multi-beams that have passed through the plurality of openings 203a of the shaping aperture array substrate 203.

The electron beam 200 emitted from the electron source 201 (emitting unit) illuminates the whole shaping aperture array substrate 203 through the illumination lens 202. The electron beam 200 illuminates a region including all of the openings 203a. When the electron beam 200 passes through the plurality of openings 203a of the shaping aperture array substrate 203, multi-beams 20a to 20e are formed as a plurality of individual beams. The whole shape of a beam array of the multi-beams 20a to 20e is, for example, a rectangular.

The individual beams forming the multi-beams 20 pass through the corresponding blankers of the blanking aperture array substrate 204. Each of the blankers performs blanking deflection of a beam to be turned off. Each of the blankers does not perform blanking deflection of a beam to be turned on. The multi-beams 20a to 20e that have passed through the blanking aperture array substrate 204 are demagnified by the reducing lens 205 and travel toward a central opening formed in the limiting aperture member 206.

An individual beam that is controlled to a beam off state is deflected by the blanker and thus travels along a path outside the opening of the limiting aperture member 206. Consequently, the individual beam is blocked by the limiting aperture member 206. Meanwhile, an individual beam that is controlled to a beam on state is not deflected by the blanker, and thus passes through the opening of the limiting aperture member 206. In this way, blanking control is performed by on/off of deflection of the blanker, and thus on/off of an individual beam is controlled. The blanking aperture array substrate 204 functions as an irradiation time control unit that controls an irradiation time of each beam of the multi-beams.

The limiting aperture member 206 allows individual beams deflected by the blankers of the blanking aperture array substrate 204 into the on state to pass therethrough and blocks individual beams deflected by the blankers of the blanking aperture array substrate 204 into the off state. A single shot of the multi-beams is formed by beams that pass through the limiting aperture member 206 during the period from the on state to the off.

The multi-beams that have passed through the limiting aperture member 206 are focused by the objective lens 207 and form a pattern image of a desired magnification on the substrate 101. The beams (whole multi-beams) passing through the limiting aperture member 206 are collectively deflected in the same direction by the deflector 208 and directed a desired position on the substrate 101.

When the XY stage 105 is continuously moving, a beam irradiation position is controlled by the deflector 208 so as to follow movement of the XY stage 105 at least while the substrate 101 is irradiated with the beams. The multi-beams that are radiated one time are ideally arranged at intervals obtained by multiplying, by the desired reduction rate, the intervals at which the plurality of openings 203a of the shaping aperture array substrate 203 are arranged.

As described above, in the writing data, a curved edge of a figure is defined by a cubic Bezier curve. As illustrated in FIG. 3, a cubic Bezier curve is represented by four control points. Among the four control points P₀ to P₃, two control points (terminal points), namely, a start point P₀ and an end point P₃, are located on the curve.

In addition, a cubic Bezier curve is a parametric curve and, illustrated in FIG. 4, a curve (x(t), y(t)) is parameterized by a parameter t (0≤t≤1).

As illustrated in FIG. 11, an ideal curve obtained by shifting a curve K0 expressed by control points C0 to C3 by a predetermined bias amount is a curve K1. There is a deviation between a curve K2 expressed by control points C10 to C13 obtained by shifting the control points C0 to C3 by a predetermined bias amount and the ideal curve K1. The present embodiment relates to calculation of control points that can express an ideal curve K1 with high accuracy.

A pattern writing method including edge bias processing according to the present embodiment is described with reference to the flowchart illustrated in FIG. 5.

In a bias amount acquisition step (step S1), the bias amount acquisition unit 111 reads out writing data from the storage unit 140 and acquires a bias amount of a curve edge of a figure pattern defined in the writing data. The bias amount acquisition unit 111 acquires bias amounts for a plurality of points (points corresponding to a plurality of parameter values) on a Bezier curve representing the curve edge. The acquired bias amounts include bias amounts T₀ and Tₘ (m is an integer of 2 or greater) at the terminal points (start point P₀ and end point Pn) and bias amounts T₁ to Tₘ₋₁ at one or more intermediate points (t=t₁ to tₘ₋₁) among multiple (n+1) control points representing a Bezier curve B₁. Each bias amount is a vector amount or a constant amount in the normal direction at a corresponding parameter value. The bias amount may be obtained by a function that depends on the curvature of a curve.

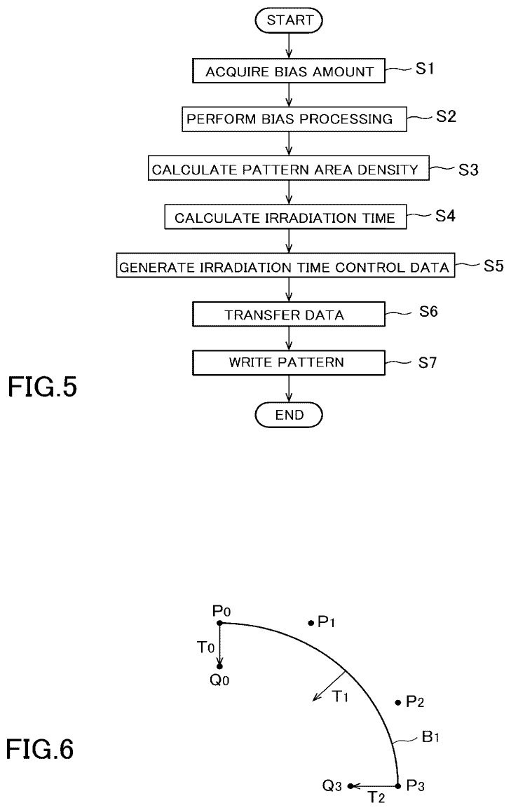

For example, as illustrated in FIG. 6, the bias amount T₀ at the start point P₀ (t=0), the bias amount T₂ at the end point P₃ (t=1), and the bias amount T₁ in the middle section (t=t₁) of the Bezier curve B1 are acquired. Each bias amount may be input to the control computer 110 from an external device or may be obtained from parameters at nearby points on the curve by interpolation using a monotonic function.

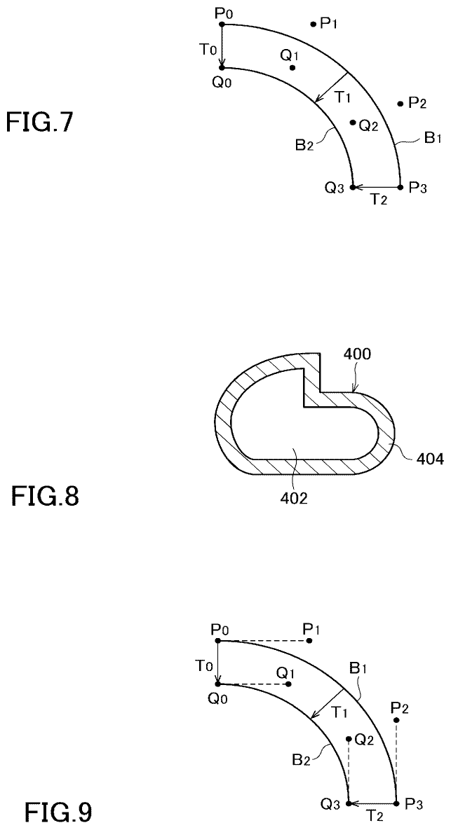

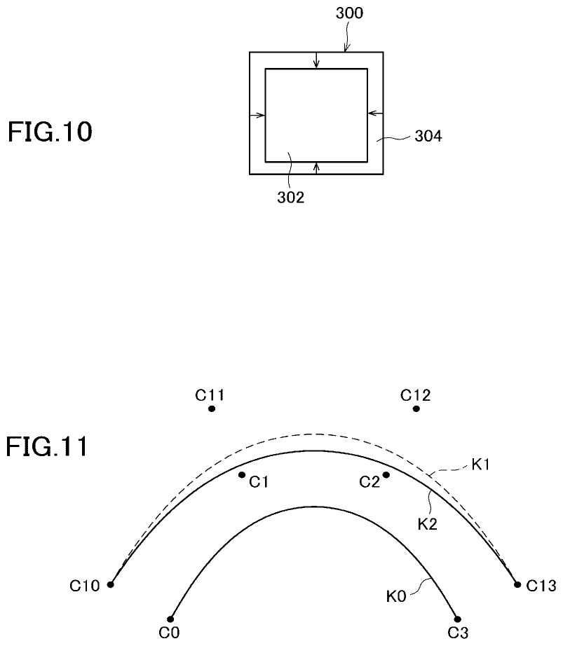

In a bias processing step (step S2), the bias processing unit 112 performs the bias processing to shift the curve edge defined in the writing data by the bias amounts. In other words, the bias processing unit 112 calculates control points Q₀ to Qₙ expressing a Bezier curve B₂ that is obtained by shifting, by the bias amounts, the Bezier curve B₁ representing the curve edge of the pattern defined in the writing data (see FIG. 7 for the Bezier curve B₂).

The bias processing unit 112 obtains points Q₀ and Qₙ by shifting the terminal points (start point P₀ and end point Pₙ) of the original Bezier curve B₁ by the respective bias amounts T₀ and Tₘ (m is an integer of 2 or greater) obtained in step S1. The points Q₀ and Qₙ are the start point and the end point, respectively, of the Bezier curve B₂ after the bias processing. For example, as illustrated in FIG. 6, the point Q₀ moved from the point P₀ (t=0) by the bias amount T₀ and the point Q₃ moved from the point P₃ by the bias amount T₂ are obtained.

The bias processing unit 112 calculates control points Q₁ to Qₙ₋₁ other than the terminal points. The control points Q₁ to Qₙ₋₁ are calculated so that the points obtained by shifting the points corresponding to the parameters t₁ to tₘ₋₁ located in the middle section of the original Bezier curve B₁ by the given bias amounts T₁ to Tₘ₋₁ and the points corresponding to the parameters t₁ to tₘ₋₁ on the Bezier curve B₂ have small norms in positional differences. For example, the bias processing unit 112 calculates the control points Q₁ to Qₙ₋₁ other than the terminal points by obtaining Qᵢ=(xᵢ, yᵢ) where D is minimized in the following formula 1 by using the least-squares method. The control points Q₁ to Qₙ₋₁ are determined by the least-squares method so that the square sums of the positional differences between the points obtained by shifting the points corresponding to the parameters t₁ to tₘ₋₁ located in the middle section of the original Bezier curve B₁ by the given bias amounts T₁ to Tₘ₋₁ and the points corresponding to the parameters t₁ to tₘ₋₁ on the Bezier curve B₂ are minimized.

$$D ( {\{ {Q}_{i} \}}_{i = 1}^{n} ) = {\sum }_{i = 1}^{m} ‖ {B}_{1} ( {t}_{i} ) + {T}_{i} - {B}_{2} ( {t}_{i} ) {‖}_{2}^{2} \qquad ( 1 )$$

For example, points Q₁ and Q₂ as illustrated in FIG. 7 are calculated by applying the above processing to the example illustrated in FIG. 6. The Bezier curve B₂ expressed by the control points Q₀ to Q₃ represents the curve obtained by shifting the Bezier curve B₁ by the bias amounts with high accuracy.

In place of the formula 1, the control points Q₁ to Qₙ₋₁ other than the terminal points may be calculated by obtaining Qᵢ=(xᵢ, yᵢ) where D is minimized in the following formula 2.

$$D ( {\{ {Q}_{i} \}}_{i = 1}^{n} ) = {\int }_{0}^{1} {‖ {B}_{1} ( t ) + T ( t ) - {B}_{2} ( t ) ‖}_{2}^{2} dt \qquad ( 2 )$$

By using the above technique, a curve edge in which a curve edge of a figure is shifted by a desired bias amount can be obtained. A straight line edge of the figure can be shifted by a bias amount by using a known technique. As a result, the edges that surround the figure can be shifted by bias amounts. For example, as illustrated in FIG. 8, a reduced pattern 402 in which an original figure pattern 400 is reduced in size can be obtained. A shaded area obtained by removing the reduced pattern 402 from the figure pattern 400 is an edge region 404.

In a pattern area density calculation step (step S3), the area density calculation unit 113 virtually divides a writing region of the substrate 101 into a plurality of rectangular mesh regions (divided regions). A size of each of the mesh regions is, for example, equivalent to a size of a single beam, and each of the mesh regions is a pixel (unit irradiation region). The area density calculation unit 113 calculates a pattern area density (coverage) p of each pixel for the pattern before the bias processing and for the pattern after the bias processing.

In an irradiation time calculation step (step S4), the irradiation time calculation unit 114 calculates an irradiation amount α·ρ·D₀ for each pixel by multiplying the pattern area density ρ calculated for the pattern before bias processing by a reference irradiation amount D₀ and a coefficient α. In addition, the irradiation time calculation unit 114 calculates an irradiation amount β·ρ·D₀ for each pixel by multiplying the pattern area density ρ calculated for the pattern after bias processing by a reference irradiation amount D₀ and a coefficient β. The coefficient α is larger than the coefficient β. The irradiation time calculation unit 114 obtains, for each pixel, a difference between the irradiation amounts after multiplication by the respective coefficients.

For example, the coefficient α corresponding to the figure pattern 400 is set to 1.2, and the coefficient β corresponding to the reduced pattern 402 is set to 0.4. By obtaining a difference in the irradiation amount, the irradiation amount of each pixel in the edge region 404 becomes ρ×D₀×1.2, and the irradiation amount of each pixel in the reduced pattern 402 area becomes ρ×D₀×0.8. Thus, the edge enhancement processing can be enabled.

The edge enhancement processing can also be performed by multiplying the pattern area density of a pixel in the edge region 404 by the reference irradiation amount D₀ and the coefficient α and multiplying the pattern area density of a pixel in the reduced pattern 402 by the reference irradiation amount D₀ and the coefficient β, which is smaller than the coefficient α.

The irradiation time calculation unit 114 calculates an irradiation time of each of the plurality of beams that constitute the multi-beams by dividing the calculated irradiation amount by a current amount of each beam.

In an irradiation time control data generation step (step S5), the data processing unit 115 generates irradiation time control data by rearranging the irradiation time data in a shot order according to a writing sequence.

In a data transfer step (step S6), the writing control unit 116 outputs the irradiation time control data to the deflection control circuit 130. The deflection control circuit 130 outputs the irradiation time control data to each blanker of the blanking aperture array substrate 204.

In a writing step (step S7), the writing control unit 116 controls the writing unit 150 to perform writing processing on the substrate 101. Each blanker of the blanking aperture array substrate 204 gives a desired exposure amount to each pixel by switching the beam on and off of a beam on the basis of the irradiation time control data.

In the above embodiment, the bias processing unit 112 may calculate the control points Q₁ to Qₙ₋₁ so that a straight line connecting the control point Q₀ and the control point Q₁ is parallel to a straight line connecting the control point P₀ and the control point P₁ and a straight line connecting the control point Qₙ₋₁ and the control point Qₙ is parallel to a straight line connecting the control point Pₙ₋₁ and the control point Pₙ. Thus, angles at connecting parts of the curve can be maintained.

In this case, the bias processing unit 112 obtains a, b, and Qᵢ=(xᵢ, yᵢ) where D is minimized in the following formula 3 to calculate the control points Q₁ to Qₙ₋₁.

$${Q}_{1} = {Q}_{0} + a ( {P}_{1} - {P}_{0} ) \qquad ( 3 )$$

$${Q}_{n - 1} = {Q}_{n} + b ( {P}_{n} - {P}_{n - 1} )$$

$$D ( {\{ {Q}_{i} \}}_{i = 1}^{n} ) = {\sum }_{i = 1}^{m} {‖ {B}_{1} ( {t}_{i} ) + {T}_{i} - {B}_{2} ( {t}_{i} ) ‖}_{2}^{2}$$

For example, points Q₁ and Q₂ as illustrated in FIG. 9 are calculated by applying the above processing to the example illustrated in FIG. 6. A straight line connecting the control point Q₀ and the control point Q₁ becomes parallel to a straight line connecting the control point P₀ and the control point P₁ and a straight line connecting the control point Q₂ and the control point Q₃ becomes parallel to a straight line connecting the control point P₂ and the control point P₃, and thus angles of the connecting parts of the curve can be maintained.

In place of the formula 3, the control points Q₁ to Qₙ₋₁ may be calculated by obtaining a, b, and Qᵢ=(xᵢ, yᵢ) where D is minimized in the following formula 4.

$${Q}_{1} = {Q}_{0} + a ( {P}_{1} - {P}_{0} ) \qquad ( 4 )$$

$${Q}_{n - 1} = {Q}_{n} + b ( {P}_{n} - {P}_{n - 1} )$$

$$D ( {\{ {Q}_{i} \}}_{i = 1}^{n} ) = {\int }_{0}^{1} {‖ {B}_{1} ( t ) + T ( t ) - {B}_{2} ( t ) ‖}_{2}^{2} dt$$

The straight line connecting the control point Q₀ and the control point Q₁ is not necessarily parallel to the straight line connecting the control point P₀ and the control point P₁ but may be slightly inclined. The straight line connecting the control point Qₙ₋₁ and the control point Qₙ is not necessarily parallel to the straight line connecting the control point Pₙ₋₁ and the control point Pₙ but may be slightly inclined. In other words, the control points Q₁ to Qₙ₋₁ may be calculated so that the straight line connecting the control point Q₀ and the control point Q₁ is generally parallel to the straight line connecting the control point P₀ and the control point P₁ and the straight line connecting the control point Qₙ₋₁ and the control point Qₙ is generally parallel to the straight line connecting the control point Pₙ₋₁ and the control point Pₙ.

Although an example in which a curve of a figure pattern is defined by a cubic Bezier curve in the writing data has been described in the above embodiment, other parametric curves, such as a B-spline curve, may also be used. In addition, the order of a parametric curve is not limited to three.

In the above embodiment, a multi-beam writing apparatus that irradiates multiple beams simultaneously using a multi-beam is described; however, the same method can also be applied to a single-beam writing apparatus that irradiates a single beam onto a target substrate.

A program that implements at least part of the functions of the control computer 110 may be distributed via a communication line such as the Internet, including wireless communication. Furthermore, the program may be encrypted, modulated, or compressed, and then distributed via a wired or wireless communication line such as the Internet, or stored on a recording medium for distribution.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A data processing method comprising:
acquiring a plurality of first control points of a first parametric curve representing a curve edge of a pattern defined in writing data;
acquiring bias amounts for points on the first parametric curve corresponding to a plurality of parameter values; and
determining a plurality of second control points such that norms of positional differences between points obtained by shifting the points on the first parametric curve by the bias amounts and points corresponding to the plurality of parameter values on a second parametric curve represented by the plurality of second control points, become small.

2. The data processing method according to claim 1, wherein
bias amounts are obtained for terminal points of the first parametric curve, and points obtained by shifting the terminal points by the bias amounts are set as terminal points of the second parametric curve.

3. The data processing method according to claim 1, wherein
the bias amounts are determined based on a curvature of the first parametric curve.

4. The data processing method according to claim 1, wherein
the plurality of second control points are determined such that a first straight line connecting a first terminal point of the first parametric curve and the first control point next to the first terminal point, and a second straight line connecting a second terminal point of the second parametric curve and the second control point next to the second terminal point are generally parallel to each other.

5. A computer-readable recording medium storing a program that causes a computer to execute:
a step of acquiring a plurality of first control points of a first parametric curve representing a curve edge of a pattern defined in writing data;
a step of acquiring bias amounts for points on the first parametric curve corresponding to a plurality of parameter values; and
a step of determining a plurality of second control points such that norms of positional differences between points obtained by shifting the points on the first parametric curve by the bias amounts and points corresponding to the plurality of parameter values on a second parametric curve represented by the plurality of second control points, become small.

6. A charged particle beam writing method comprising:
reading writing data from a storage unit;
acquiring a plurality of first control points of a first parametric curve representing a curve edge of a first pattern defined in the writing data;
acquiring bias amounts for points on the first parametric curve corresponding to a plurality of parameter values;
determining a plurality of second control points such that norms in positional differences between points obtained by shifting the points on the first parametric curve by the bias amounts and points corresponding to the plurality of parameter values on a second parametric curve represented by the plurality of second control points, become small;
virtually dividing a writing region of a substrate into a plurality of pixels having a predetermined mesh size;
calculating an area density of a second pattern including the second parametric curve for each of the pixels;
calculating a beam irradiation amount from the area density; and
irradiating the substrate with a charged particle beam at the beam irradiation amount.

7. The charged particle beam writing method according to claim 6, wherein
the second pattern is a reduced pattern of the first pattern, and
the beam irradiation amount for an edge region obtained by removing the second pattern from the first pattern is greater than the beam irradiation amount for the second pattern.

8. A charged particle beam writing apparatus comprising;
a storage unit storing writing data in which a plurality of first control points of a first parametric curve representing a curve edge of a first pattern are defined;
a bias amount acquisition unit reading the writing data from the storage unit and acquiring bias amounts for points on the first parametric curve corresponding to a plurality of parameter values;
a bias processing unit determining a plurality of second control points such that norms in positional differences between points obtained by shifting the points on the first parametric curve by the bias amounts and points corresponding to the plurality of parameter values on a second parametric curve represented by the plurality of second control points, become small;
an area density calculation unit virtually dividing a writing region of a substrate into a plurality of pixels of a predetermined mesh size and calculating an area density of a second pattern including the second parametric curve for each of the pixels; and
a writing unit irradiating the substrate with a charged particle beam at a beam irradiation amount calculated from the area density.

9. The charged particle beam writing apparatus according to claim 8, wherein
the second pattern is a reduced pattern of the first pattern, and
the beam irradiation amount for an edge region obtained by removing the second pattern from the first pattern is greater than the beam irradiation amount for the second pattern.
